(19) United States
(12) Patent Application Publication
(10) Pub. No.: US 2020/0110579 A1
(43) Pub. Date: Apr. 9, 2020

(54) ARGMAX FUNCTION ANALOG CIRCUIT

(71) Applicant: INTERNATIONAL BUSINESS MACHINES CORPORATION, Armonk, NY (US)

(72) Inventors: Xin Zhang, Yorktown Heights, NY (US); Dennis M. Newns, Yorktown Heights, NY (US); Xiaodong Cui, Chappaqua, NY (US); Jin Ping Han, Yorktown Heights, NY (US)

(21) Appl. No.: 16/153,232

(22) Filed: Oct. 5, 2018

(51) Int. Cl. G06F 7/22; H03K 5/24; G06N 3/063

(52) U.S. Cl. CPC G06F 7/22; G06N 3/0635; H03K 5/24

(57) ABSTRACT

An argmax circuit includes input nodes coupled to a first set of comparators to receive a plurality of analog input signals each associated with a channel number, the first set of comparators outputting a plurality of first analog results and input nodes coupled to a second set of comparators to receive and process the plurality of first analog results, the second set of comparators outputting a plurality of second analog results processed by additional comparators in a cascading manner in a forward direction until a single comparator remains with a single output. A plurality of comparators including the first set, the second set, and the additional comparators are executed in a reverse direction to determine the channel number from which the single output originated from.

### BACKGROUND

### Technical Field

The present invention relates generally to deep neural network classification circuits, and more specifically, to an argmax function analog circuit employed in deep neural networks.

### Description of the Related Art

Neuromorphic and synaptronic computation, also referred to as artificial neural networks, are computational systems that permit electronic systems to essentially function in a manner analogous to that of biological brains. Neuromorphic and synaptronic computation do not generally utilize the traditional digital model of manipulating 0s and 1s. Instead, neuromorphic and synaptronic computation create connections between processing elements that are roughly functionally equivalent to neurons of a biological brain. Neuromorphic and synaptronic computation can include various electronic circuits that are modeled on biological neurons.

### SUMMARY

In accordance with an embodiment, an argmax circuit is provided. The argmax circuit includes input nodes coupled to a first set of comparators to receive a plurality of analog input signals each associated with a channel number, the first set of comparators outputting a plurality of first analog results and input nodes coupled to a second set of comparators to receive and process the plurality of first analog results, the second set of comparators outputting a plurality of second analog results processed by additional comparators in a cascading manner in a forward direction until a single comparator remains with a single output. A plurality of comparators including the first set, the second set, and the additional comparators are executed in a reverse direction to determine the channel number from which the single output originated from.

In accordance with another embodiment, an argmax circuit is provided. The argmax circuit includes input nodes coupled to a first set of comparators to receive a plurality of analog input signals each associated with a channel number, the first set of comparators outputting a plurality of first analog results and input nodes coupled to a second set of comparators to receive and process the plurality of first analog results, the second set of comparators outputting a plurality of second analog results processed by additional comparators in a cascading manner in a forward direction until a single comparator remains with a single output. A plurality of comparators including the first set, the second set, and the additional comparators are executed such that digital outputs of each of the plurality of comparators are fed into digital mini-processors to determine the channel number from which the single output originated from.

In accordance with yet another embodiment, an argmax circuit is provided. The argmax circuit includes 2ⁿ analog input signals coupled to 2ⁿ⁻¹ analog comparison unit circuits, where each analog comparison unit circuit takes two of the 2ⁿ analog input signals and generates 2ⁿ⁻¹ analog output signals representing a larger one of the two inputs in each analog comparison unit circuit and 2ⁿ⁻¹ digital output signals; and 2ⁿ⁻¹ analog output signals coupled to 2ⁿ⁻² analog comparison unit circuits, where each analog comparison unit circuit takes two of the 2ⁿ⁻¹ analog input signals and generates 2ⁿ⁻² analog output signals, representing a larger one of the two inputs in each analog comparison unit circuit and 2ⁿ⁻² digital output signals, where such circuit topology is repeated until there is only one analog comparison unit circuit which generates a final analog output.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE SEVERAL VIEWS OF THE DRAWINGS

The invention will provide details in the following description of preferred embodiments with reference to the following figures wherein:

FIG. 1 is a block/flow diagram of an example analog circuit for determining the argmax or argmin function, in accordance with an embodiment of the present invention;

FIG. 2 is a block/flow diagram of another example analog circuit for determining the argmax or argmin function, in accordance with another embodiment of the present invention;

FIG. 3 is a block/flow diagram illustrating a unit circuit, in accordance with an embodiment of the present invention; and

FIG. 4 is an exemplary processing system for deep neural network classification circuits, in accordance with embodiments of the present invention.

Throughout the drawings, same or similar reference numerals represent the same or similar elements.

### DETAILED DESCRIPTION

Embodiments in accordance with the present invention provide methods and devices for employing an analog argmax or argmin circuit in deep neural networks. Inference in deep neural network classification circuits needs the argmax function at the output. The argmax function is defined as follows: given N analog input channels, find the largest input and the number of the channel with the largest input. The exemplary embodiments of the present invention realize the argmax function in analog circuitry. Cascaded units are employed in the forward direction to generate a maximum analog value. Cascaded units are employed in the reverse direction, in one implementation, to determine a channel number with the maximum analog value. Cascaded units are employed in another implementation, such that unit digital outputs are collected in digital mini-processors, which output the number of the channel that carries the maximum analog value. Of course, one skilled in the art can contemplate employing the cascaded units to generate a minimum analog value.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

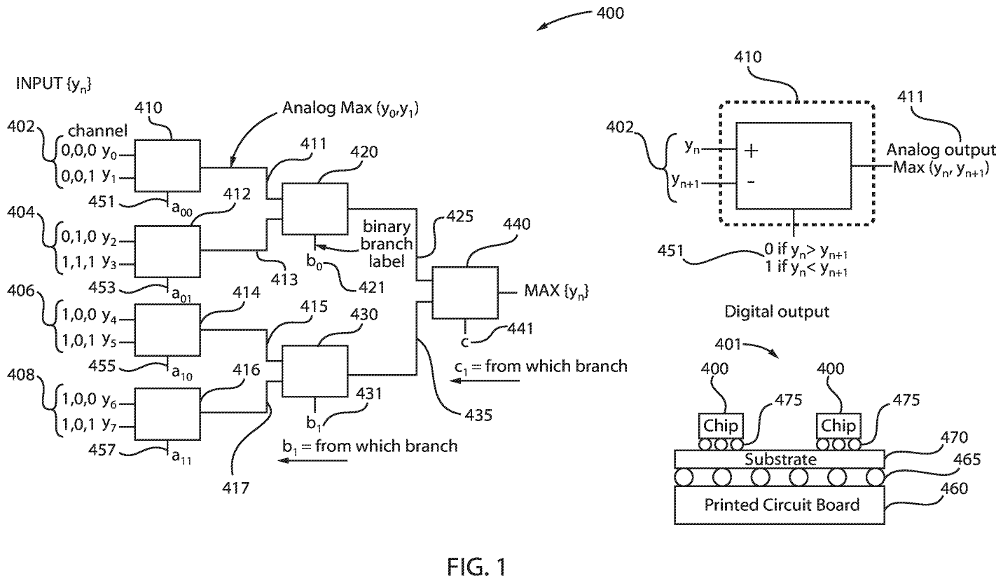

FIG. 1 is a block/flow diagram of an example analog circuit for determining the argmax or argmin function, in accordance with an embodiment of the present invention.

A neural network having multiple layers can be used to compute inferences. For example, given an input, the neural network can compute an inference for the input. The neural network computes this inference by processing the input through each of the layers of the neural network. In particular, the layers of the neural network are arranged in a sequence, each with a respective set of weights. Each layer receives an input and processes the input in accordance with the set of weights for the layer to generate an output.

Therefore, in order to compute an inference from a received input, the neural network receives the input and processes it through each of the neural network layers in the sequence to generate the inference, with the output from one neural network layer being provided as input to the next neural network layer. Data inputs to a neural network layer, e.g., either the input to the neural network or the outputs of the layer below the layer in the sequence, to a neural network layer can be referred to as activation inputs to the layer.

In some implementations, the layers of the neural network are arranged in a directed graph. That is, any particular layer can receive multiple inputs, multiple outputs, or both. The layers of the neural network can also be arranged such that an output of a layer can be sent back as an input to a previous layer.

Some neural networks normalize outputs from one or more neural network layers to generate normalized values that are used as inputs to subsequent neural network layers. Normalizing the outputs can help ensure the normalized values remain within expected domains for the inputs of the subsequent neural network layers. This can reduce errors in inference calculations.

Some neural networks pool outputs from one or more neural network layers to generate pooled values that are used as inputs to subsequent neural network layers. In some implementations, the neural network pools a group of outputs by determining a maximum (or minimum) or average of the group of outputs and using the maximum (or minimum) or average as the pooled output for the group. Pooling the outputs can maintain some spatial invariance so the outputs arranged in various configurations can be processed to have the same inference. Pooling the outputs can also reduce dimensionality of inputs received at the subsequent neural network layers while maintaining desired characteristics of the outputs before pooling, which can improve efficiency without significantly compromising the quality of inferences generated by the neural networks.

This specification describes special-purpose hardware circuitry that computes the argmax (or argmin) function in deep learning. The arguments of the maxima (abbreviated arg max or argmax) are the points of the domain of some function at which the function values are maximized. In contrast to global maxima, referring to the largest outputs of a function, arg max refers to the inputs, or arguments, at which the function outputs are as large as possible.

Analog circuit 400 receives input analog datasets in channels defined by binary notation. The analog circuit 400 can be incorporated onto a semiconductor structure 401 including a substrate 470 connected to a printed circuit board 460 via solder balls 465. The chips (including the analog circuitry 400) can be connected to the substrate 470 by solder bumps 475.

The substrate 470 can be crystalline, semi-crystalline, microcrystalline, or amorphous. The substrate 470 can be essentially (e.g., except for contaminants) a single element (e.g., silicon), primarily (e.g., with doping) of a single element, for example, silicon (Si) or germanium (Ge), or the substrate 470 can include a compound, for example, Al₂O₃, SiO₂, GaAs, SiC, or SiGe. The substrate 470 can also have multiple material layers. In some embodiments, the substrate 470 includes a semiconductor material including, but not necessarily limited to, silicon (Si), silicon germanium (SiGe), Si:C (carbon doped silicon), carbon doped silicon germanium (SiGe:C), carbon doped silicon germanium (SiGe:C), III-V (e.g., GaAs, AlGaAs, InAs, InP, etc.), II-V compound semiconductor (e.g., ZnSe, ZnTe, ZnCdSe, etc.) or other like semiconductor. In addition, multiple layers of the semiconductor materials can be used as the semiconductor material of the substrate 470.

In one example, analog dataset y₀ is received in channel {0, 0, 0} and analog dataset y₁ is received in channel {0, 0, 1}. The analog datasets 402 (y₀, y₁) are received in comparator 410. The comparator 410 compares the two inputs y₀ and y₁ to determine which is larger. The larger value 411 is then input into comparator 420. The binary branch label 451 is designated as a₀₀. The binary branch label 451 is a digital output.

Similarly, analog dataset y₂ is received in channel {0, 1, 0} and analog dataset y₃ is received in channel {1, 1, 1}. The analog datasets 404 (y₂, y₃) are received in comparator 412. The comparator 412 compares the two inputs y₂ and y₃ to determine which is larger. The larger value 413 is then input into comparator 420. Thus comparator 420 has received values 411 and 413. These values are compared to determine which is larger. The larger value 425 is then input into comparator 440. The binary branch label 421 is designated as b₀. The binary branch label 453 is designated as a₀₁. The binary branch labels 421, 453 are digital outputs.

Similarly, analog dataset y₄ is received in channel {1, 0, 0} and analog dataset y₅ is received in channel {1, 0, 1}. The analog datasets 406 (y₄, y₅) are received in comparator 414. The comparator 414 compares the two inputs y₄ and y₅ to determine which is larger. The larger value 415 is then input into comparator 430. The binary branch label 455 is designated as a₁₀. The binary branch label 455 is a digital output.

Similarly, analog dataset y₆ is received in channel {1, 0, 0} and analog dataset y₇ is received in channel {1, 0, 1}. The analog datasets 408 (y₆, y₇) are received in comparator 416. The comparator 416 compares the two inputs y₆ and y₇ to determine which is larger. The larger value 417 is then input into comparator 430. Thus comparator 430 has received values 415 and 417. These values are compared to determine which is larger. The larger value 435 is then input into comparator 440. The binary branch label 431 is designated as b₁. The binary branch label 457 is designated as all. The binary branch labels 431 and 457 are digital outputs.

Now comparator 440 has received two values, that is values 425 and 435. Comparator 440 compares values 425 and 435 to determine which is larger. The larger value is designated as MAX{yₙ}. The binary branch label 441 is designated as c. The binary branch label 441 is a digital output.

This process can be referred to as a cascaded process in the forward direction (to the right) or cascaded binary sort that generates the maximum analog value from datasets y₀, y₁, y₂, y₃, y₄, y₅, y₆, y₇. The largest value output from each comparator is stored as a binary digit. The term ‘cascade” can refer to a series or succession of stages such that each stage is derived from or acts upon the product or result of the preceding or previous stage.

After the largest value MAX{yₙ} is determined, the process proceeds to the left thus commencing an inverted cascaded process. The inverted cascaded process employs the binary branching labels c, b₀, b₁, a₀₀, a₀₁, a₁₀, a₁₁ to determine which branch to choose. The full number is the binary address of MAX{yₙ}. In other words, the cascaded units are employed in the reverse direction to determine the channel number with the maximum analog value (or minimum analog value by employing the smallest value MINI{yₙ}).

In one example, it is determined by comparator 410 that y₀>y₁. Thus, y₀ is value 411 fed into comparator 420. It is further determined by comparator 412 that y₃>y₂. Thus, y₃ is value 413 fed into comparator 420. Comparator 420 then compares y₀ and y₃ (the larger values), and determines that y₃>y₀. As a result, y₃ is value 425 fed into comparator 440.

Similarly, it is determined by comparator 414 that y₅>y₄. Thus, y₅ is value 415 fed into comparator 430. It is further determined by comparator 416 that y₆>y₇. Thus, y₆ is value 417 fed into comparator 430. Comparator 430 then compares y₅ and y₆ (the larger values), and determines that y₆>y₅. As a result, y₆ is value 435 fed into comparator 440.

Comparator 440 compares y₃ and y₆ (the larger values), and determines that y₃>y₆. Thus, the maximum analog value is y₃. This was determined by cascaded units employed in a forward direction (to the right). Now a user wants to determine where the maximum analog value y₃ came from (i.e., from which channel) or originated from. The cascaded units are now employed in a reverse direction to determine the channel number with the maximum analog value y₃. The branching labels are utilized to conduct such investigation. The branch label 441 (or c) determines which previous branch the value y₃ came from or originated from. It is determined that y₃ came from branch b₀ (not branch b₁). Then, the branch label 421 (or b₀) determines which previous branch the value y₃ came from or originated from. It is determined that y₃ came from branch a₀₁ (not branch a₀₀). Therefore, the binary address of y₃ is (c, b₀, a₀₁) and the channel of y₃ is {1, 1, 1}.

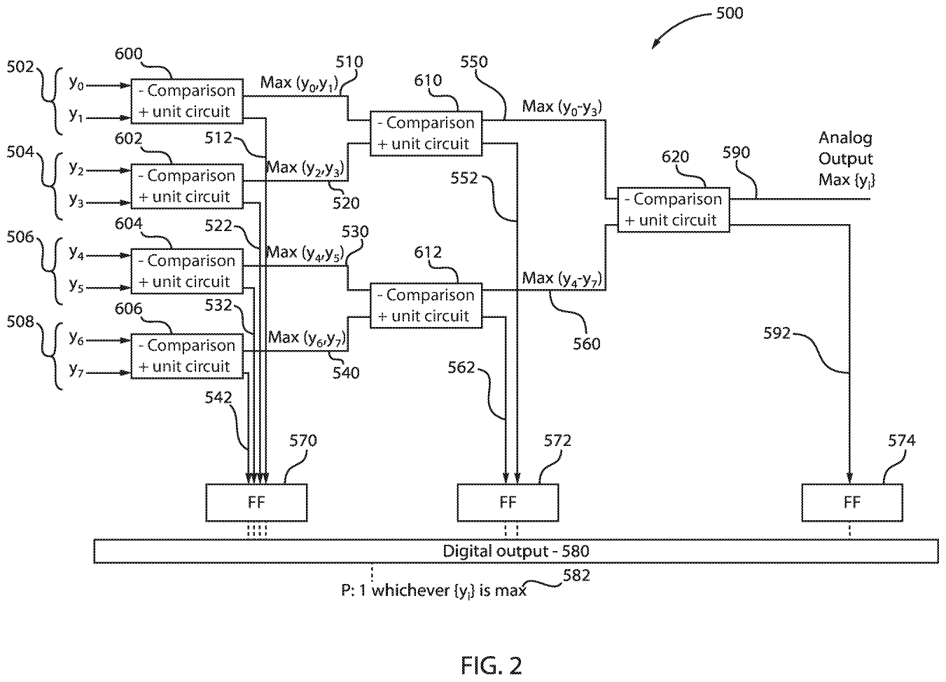

FIG. 2 is a block/flow diagram of another example analog circuit for determining the argmax or argmin function, in accordance with another embodiment of the present invention.

Analog circuit 500 receives input analog datasets in channels defined by binary notation.

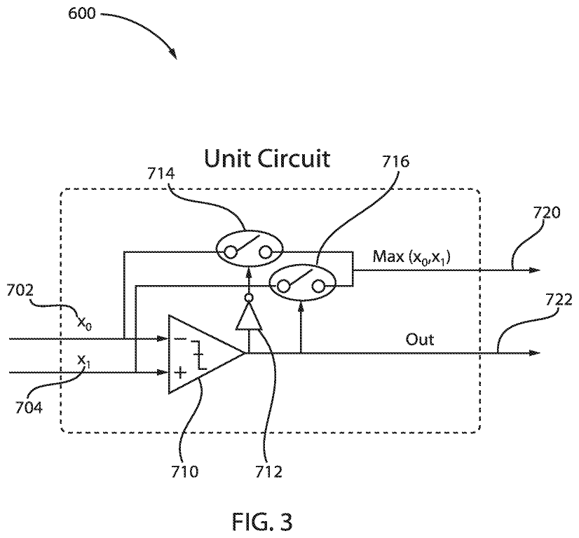

For example, analog dataset y₀ is received in channel {0, 0, 0} and analog dataset y₁ is received in channel {0, 0, 1}. The analog datasets 502 (y₀, y₁) are received in comparator 600 (FIG. 3). The comparator 600 compares the two inputs y₀ and y₁ to determine which is larger. The larger value 510 is then input into comparator 610 (similar to comparator 600).

Similarly, analog dataset y₂ is received in channel {0, 1, 0} and analog dataset y₃ is received in channel {1, 1, 1}. The analog datasets 504 (y₂, y₃) are received in comparator 602. The comparator 602 compares the two inputs y₂ and y₃ to determine which is larger. The larger value 520 is then input into comparator 610. Thus comparator 610 has received values 510 and 520. These values are compared to determine which is larger. The larger value 550 is then input into comparator 620 (similar to comparator 600).

Similarly, analog dataset y₄ is received in channel {1, 0, 0} and analog dataset y₅ is received in channel {1, 0, 1}. The analog datasets 506 (y₄, y₅) are received in comparator 604. The comparator 604 compares the two inputs y₄ and y₅ to determine which is larger. The larger value 530 is then input into comparator 612.

Similarly, analog dataset y₆ is received in channel {1, 0, 0} and analog dataset y₇ is received in channel {1, 0, 1}. The analog datasets 508 (y₆, y₇) are received in comparator 606. The comparator 606 compares the two inputs y₆ and y₇ to determine which is larger. The larger value 540 is then input into comparator 612 (similar to comparator 600). Thus comparator 612 has received values 530 and 540. These values are compared to determine which is larger. The larger value 560 is then input into comparator 620.

Now comparator 620 has received two values, that is values 550 and 560. Comparator 620 compares values 550 and 560 to determine which is larger. The larger value is designated as MAX{yᵢ} or value 590. This process can be referred to as a cascaded process in the forward direction (to the right) or cascaded binary sort that generates the maximum analog value (or minimum analog value) from datasets y₀, y₁, y₂, y₃, y₄, y₅, y₆, y₇. The largest value output from each comparator is stored as a binary digit.

As the largest value MAX{yᵢ} is being determined, the unit digital outputs are collected in a digital mini-processors (e.g., flip-flops), which output the number of the channel that carries the maximum analog value (or minimum analog value). For example, mini-processor or flip-flop (FF) 570 collects such values 512, 522, 532, 542 from comparators 600, 602, 604, 606. Mini-processor or flip-flop (FF) 572 collects such values 552, 562 from comparators 610, 612. Moreover, mini-processor or flip-flop (FF) 574 collects such value 592 from comparator 620. The values collected by FFs 570, 572, 574 are fed into a digital output processor 580 that determines which channel the largest value MAX{yᵢ} came from or originated from. The channel output 582 is then assigned to the largest value MAX{yᵢ}. Thus, the channel numbers are determined differently with respect to circuit 400 (FIG. 1) and circuit 500 (FIG. 2).

In one example, it is determined by comparator 600 that y₀>y₁. Thus, y₀ is value 510 fed into comparator 610. It is further determined by comparator 602 that y₃>y₂. Thus, y₃ is value 520 fed into comparator 610. Comparator 610 then compares y₀ and y₃ (the larger values), and determines that y₃>y₀. As a result, y₃ is value 550 fed into comparator 620.

Similarly, it is determined by comparator 604 that y₅>y₄. Thus, y₅ is value 530 fed into comparator 612. It is further determined by comparator 606 that y₆>y₇. Thus, y₆ is value 540 fed into comparator 612. Comparator 612 then compares y₅ and y₆ (the larger values), and determines that y₆>y₆. As a result, y₆ is value 560 fed into comparator 620.

Comparator 620 compares y₃ and y₆ (the larger values), and determines that y₃>y₆. Thus, the maximum analog value is y₃. This was determined by cascaded units employed in a forward direction (to the right). Now a user wants to determine where the maximum analog value y₃ came from (i.e., from which channel) or originated from. The FFs 570, 572, 574 collected such data from each comparison and fed the results 512, 522, 532, 542, 552, 562, 592 into digital output processor 580 that outputs channel output 582 as the channel number {1, 1, 1} from where y₃ came from or originated from.

FIG. 3 is a block/flow diagram illustrating a unit circuit, in accordance with an embodiment of the present invention.

The unit circuit 600 includes two inputs 702 and 704 that are fed into comparator 710. The comparison results are fed into inverter 712 and switches 714, 716 to generate outputs 720, 722. Output 720 provides the larger value of inputs 702, 704, whereas output 722 provides the smaller value of inputs 702, 704. The unit circuit 600 can be used in both circuit designs 400 and 500. The unit circuits 600, 602, 604, 606, 610, 612, 620 can be similar structural and functioning units.

The circuits 400 and 500 can be employed in the realm of machine learning. A machine learning model such as an artificial neural network, which can include an interconnected group of artificial neurons (e.g., neuron models), is a computational device or represents a method to be performed by a computational device.

Convolutional neural networks are a type of feed-forward artificial neural network. Convolutional neural networks can include collections of neurons that each have a receptive field and that collectively tile an input space. Convolutional neural networks (CNNs) have numerous applications. Deep learning architectures, such as deep belief networks and deep convolutional networks, are layered neural networks architectures in which the output of a first layer of neurons becomes an input to a second layer of neurons, the output of a second layer of neurons becomes and input to a third layer of neurons, and so on. Deep neural networks can be trained to recognize a hierarchy of features and so they have increasingly been used in object recognition applications. Like convolutional neural networks, computation in these deep learning architectures can be distributed over a population of processing nodes, which can be configured in one or more computational chains. These multi-layered architectures can be trained one layer at a time and can be fine-tuned using back propagation. The circuits 400 and 500 can be employed in CNNs.

In summary, the exemplary embodiments of the present invention employ an analog argmax (or argmin) circuit in deep neural networks. Inference in deep neural network classification circuits needs the argmax function at the output. The exemplary embodiments of the present invention realize the argmax (or argmin) function in analog circuitry. Cascaded units are employed in the forward direction to generate a maximum analog value (or minimum analog value). Cascaded units are employed in the reverse direction, in one implementation, to determine a channel number with the maximum analog value (or minimum analog value). Cascaded units are employed in another implementation, such that unit digital outputs are collected in digital mini-processors, which output the number of the channel that carries the maximum analog value (or minimum analog value).

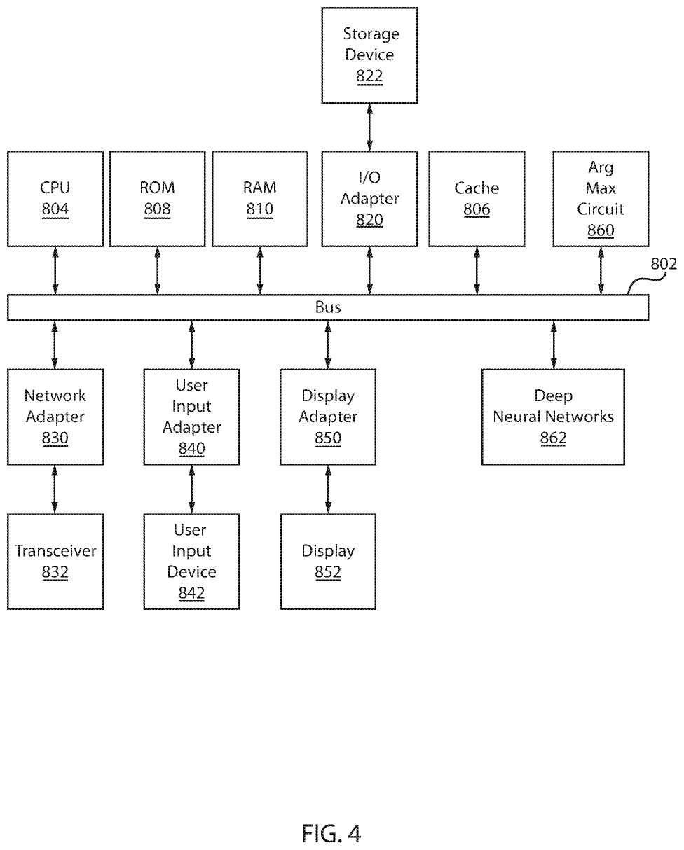

FIG. 4 is an exemplary processing system for deep neural network classification circuits, in accordance with embodiments of the present invention.

The processing system includes at least one processor (CPU) 804 operatively coupled to other components via a system bus 802. A cache 806, a Read Only Memory (ROM) 808, a Random Access Memory (RAM) 810, an input/output (I/O) adapter 820, a network adapter 830, a user interface adapter 840, and a display adapter 850, are operatively coupled to the system bus 802. Moreover, deep neural networks 862 can be connected to the system bus 802. The deep neural networks 862 can employ an argmax function analog circuit 860.

A storage device 822 is operatively coupled to system bus 802 by the I/O adapter 820. The storage device 822 can be any of a disk storage device (e.g., a magnetic or optical disk storage device), a solid state magnetic device, and so forth.

A transceiver 832 is operatively coupled to system bus 802 by network adapter 830.

User input devices 842 are operatively coupled to system bus 802 by user interface adapter 840. The user input devices 842 can be any of a keyboard, a mouse, a keypad, an image capture device, a motion sensing device, a microphone, a device incorporating the functionality of at least two of the preceding devices, and so forth. Of course, other types of input devices can also be used, while maintaining the spirit of the present invention. The user input devices 842 can be the same type of user input device or different types of user input devices. The user input devices 842 are used to input and output information to and from the processing system.

A display device 852 is operatively coupled to system bus 802 by display adapter 850.

Of course, the processing system employing the argmax analog circuit can also include other elements (not shown), as readily contemplated by one of skill in the art, as well as omit certain elements. For example, various other input devices and/or output devices can be included in the system, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized as readily appreciated by one of ordinary skill in the art. These and other variations of the processing system employing the argmax analog circuit are readily contemplated by one of ordinary skill in the art given the teachings of the present invention provided herein.

As used herein, the term “determining” encompasses a wide variety of actions. For example, “determining” can include calculating, computing, processing, deriving, investigating, looking up (e.g., looking up in a table, a database or another data structure), ascertaining and the like. Additionally, “determining” can include receiving (e.g., receiving information), accessing (e.g., accessing data in a memory) and the like. Furthermore, “determining” can include resolving, selecting, choosing, establishing and the like.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device.

It is to be understood that the present invention will be described in terms of a given illustrative architecture; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The present embodiments may include a design for an integrated circuit chip, which may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, may be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly. In addition, it will also be understood that when a layer is referred to as being “between” two layers, it can be the only layer between the two layers, or one or more intervening layers may also be present.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

Having described preferred embodiments of an argmax (or argmin) function analog circuit employed in deep neural networks (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

What is claimed is:

1. A circuit comprising:
input nodes coupled to a first set of comparators to receive a plurality of analog input signals each associated with a channel number, the first set of comparators outputting a plurality of first analog results; and
input nodes coupled to a second set of comparators to receive and process the plurality of first analog results, the second set of comparators outputting a plurality of second analog results processed by additional comparators in a cascading manner in a forward direction until a single comparator remains with a single output;
wherein a plurality of comparators including the first set, the second set, and the additional comparators are executed in a reverse direction to determine the channel number from which the single output originated from.

2. The circuit of claim 1, wherein the single output includes a maximum or minimum analog value.

3. The circuit of claim 2, wherein each of the plurality of comparators is associated with a binary branch label.

4. The circuit of claim 3, wherein the channel number of the maximum or minimum analog value is defined as a sequence of binary branch labels.

5. The circuit of claim 3, wherein the binary branch labels are digital outputs.

6. The circuit of claim 1, wherein the argmax circuit is employed in deep neural networks.

7. A circuit comprising:
input nodes coupled to a first set of comparators to receive a plurality of analog input signals each associated with a channel number, the first set of comparators outputting a plurality of first analog results; and
input nodes coupled to a second set of comparators to receive and process the plurality of first analog results, the second set of comparators outputting a plurality of second analog results processed by additional comparators in a cascading manner in a forward direction until a single comparator remains with a single output;
wherein a plurality of comparators including the first set, the second set, and the additional comparators are executed such that digital outputs of each of the plurality of comparators are fed into digital mini-processors to determine the channel number from which the single output originated from.

8. The circuit of claim 7, wherein the single output includes a maximum or minimum analog value.

9. The circuit of claim 8, wherein the digital mini-processors are flip-flops.

10. The circuit of claim 9, wherein outputs from the flip-flops are fed into a digital output processor that provides the channel number from which the single output originated from.

11. The circuit of claim 10, wherein each of the plurality of comparators includes a comparison unit, an inverter, and two switches.

12. The circuit of claim 7, wherein the argmax circuit is employed in deep neural networks.

13. An argmax circuit comprising:
2ⁿ analog input signals coupled to 2ⁿ⁻¹ analog comparison unit circuits, where each analog comparison unit circuit takes two of the 2ⁿ analog input signals and generates 2ⁿ⁻¹ analog output signals representing a larger one of the two inputs in each analog comparison unit circuit and 2ⁿ⁻¹ digital output signals; and
2ⁿ⁻¹ analog output signals coupled to 2ⁿ⁻² analog comparison unit circuits, where each analog comparison unit circuit takes two of the 2ⁿ⁻¹ analog input signals and generates 2ⁿ⁻² analog output signals, representing a larger one of the two inputs in each analog comparison unit circuit and 2ⁿ⁻² digital output signals, where such circuit topology is repeated until there is only one analog comparison unit circuit which generates a final analog output.

14. The argmax circuit of claim 13, wherein the 2ⁿ⁻¹ analog comparison unit circuits, the 2ⁿ⁻² analog comparison unit circuits, and any additional analog comparison unit circuits are executed in a reverse direction to determine a channel number from which the final analog output originated from.

15. The argmax circuit of claim 14, wherein each of the analog comparison unit circuits is associated with a binary branch label.

16. The argmax circuit of claim 15, wherein the channel number of the final analog output is defined as a sequence of binary branch labels.

17. The argmax circuit of claim 13, wherein the 2ⁿ⁻¹ analog comparison unit circuits, the 2ⁿ⁻² analog comparison unit circuits, and any additional analog comparison unit circuits are manipulated such that digital outputs of each of the analog comparison unit circuits are fed into digital mini-processors to determine a channel number from which the final analog output originated from.

18. The argmax circuit of claim 17, wherein the digital mini-processors are flip-flops.

19. The argmax circuit of claim 13, wherein the 2ⁿ analog input signals include m meaningful analog input signals and (2²−m) analog input signals.

20. The argmax circuit of claim 13, wherein the argmax circuit is employed in deep neural networks.
